(19) United States
(12) Patent Application Publication
(10) Pub. No.: US 2010/0237326 A1
(43) Pub. Date: Sep. 23, 2010

(54) ORGANIC TRANSISTOR AND MANUFACTURING METHOD THEREOF

(76) Inventor: Satoru Ohta, Saitama (JP)

Correspondence Address: WENDEROTH, LIND & PONACK, L.L.P., 1030 15th Street, N.W.,, Suite 400 East, Washington, DC, 20005-1503, US

(21) Appl. No.: 12/224,502

(22) PCT Filed: Dec. 27, 2006
(86) PCT No.: PCT/JP2006/326093

§ 371 Date: Jun. 7, 2010

(30) Foreign Application Priority Data
Feb. 28, 2006 (JP) 2006-051657

(51) Int. Cl. H01L 51/10; H01L 51/40

(52) U.S. Cl. 257/40; 438/99; 257/E51.007

(57) ABSTRACT

An organic transistor including a substrate 1, a pair of a source electrode 4 and a drain electrode 5, an organic semiconductor layer 6 provided between the source electrode 4 and the drain electrode 5, and a gate electrode 2 provided in association with the organic semiconductor 6 with a gate insulating layer 3 interposed therebetween, wherein the gate insulating layer 3 includes an organic insulating layer 3a containing an insulating organic material and a barrier layer 3b covering a surface of the organic insulating layer and having process resistance.

### TECHNICAL FIELD

The present invention relates to an organic transistor and a manufacturing method thereof.

### BACKGROUND ART

Organic transistors can be formed by using a flexible organic material capable of being applied as a coating and are expected to be used for driving elements of displays and IC tags. An organic transistor having a MOS-FET (metal oxide semiconductor field-effect transistor) structure includes a gate electrode, a gate insulating layer, a source electrode, a drain electrode, and an organic semiconductor layer which are formed over a substrate. A voltage is applied between the source electrode and the drain electrode from the gate electrode through the gate insulating layer to control an electric current passing through the organic semiconductor layer.

Organic TFTs (thin film transistors) have been studied actively in recent years, and it is expected that the organic TFTs will be applied, for example, to flexible displays by virtue of the flexibility of an organic semiconductor itself and the use of a resin substrate. In the organic TFTs, semiconductor layers are typically formed by vapor deposition. Pentacene, one of materials studied most actively, exhibits a mobility of 1 cm²/Vs or higher which is equal to or higher than that of amorphous silicon, and is expected to be used more widely in an organic semiconductor element.

To make the best possible use of the organic TFTs, various attempts have been made to form organic TFTs by coating application including the use of printing techniques with the aim of a low-cost process. Specifically, attempts have been made to form a film of polyalkylthiophene which is a polymeric semiconductor or a low-molecular-weight material such as a pentacene precursor by coating application. In addition to the semiconductor layer, the gate insulating layer has been studied to develop a material thereof soluble in a solvent such as a polymer which can be formed into a film by coating application.

Japanese Patent Laid-Open No. 2002-110999 has proposed a gate insulating film formed of a polymeric material having a high dielectric constant by including fine particles of metal oxide having a high dielectric constant dispersed in an amorphous insulator formed of a polymeric material having a high dielectric constant and containing a cyano group such as cyanoehylpullulan. The polymeric material having a high dielectric constant, however, generally has a low volume resistivity and is significantly polarized to have localized carriers, which tends to reduce the performance of the resulting transistor and have a poor surface property.

On the other hand, each of Japanese Patent Laid-Open Nos. 2005-72569 and 2005-26698 has proposed a high-performance organic transistor by using a gate insulating layer of stacked structure in which an insulating layer having a high dielectric constant is used for a first layer closer to a gate electrode and a flat polymeric material having a low dielectric constant is used for a second layer.

### DISCLOSURE OF THE INVENTION

### Problems to be Solved by the Invention

When the gate insulating layer includes a polymeric material, however, an ion component contained in an alkaline developer or acid etchant used in an etching or lift-off step may enter the gate insulating layer during formation of a source electrode and a drain electrode. In addition, during formation of the organic semiconductor layer by coating application, an ion component contained in a solvent for solving the organic semiconductor, an ion component contained in the organic semiconductor when the organic semiconductor material can be applied as a coating, or the low-molecular-weight organic semiconductor itself when the organic semiconductor material can be applied as a coating may penetrate the gate insulating layer including a polymeric material. If the ion component or the organic semiconductor material enters the gate insulating layer, the problem of deteriorated insulation resistance of the gate insulating layer arises. In this manner, when the gate insulating layer containing a polymeric material is used, the problem of the damage to the gate insulating layer may occur during process, by way of example.

The problem can be addressed by forming a gate insulating layer made of an inorganic material such as SiO₂ through sputtering or the like. However, if the gate insulating material is formed only of an inorganic material, the resulting flexible substrate suffers from a poor bending strength and cracks are produced when it is bent, for example.

It is thus an object of the present invention to provide an organic transistor with high performance which can be used for a flexible substrate and can prevent damage to a gate insulating layer during process.

### Means for Solving Problems

As described in claim 1, the present invention provides an organic transistor including a substrate, a pair of a source electrode and a drain electrode, an organic semiconductor layer provided between the source electrode and the drain electrode, and a gate electrode provided in association with the organic semiconductor layer with a gate insulating layer interposed therebetween, wherein the gate insulating layer includes an organic insulating layer containing an insulating organic material and a barrier layer covering a surface of the organic insulating layer and having process resistance.

As described in claim 9, the present invention provides a method of manufacturing an organic transistor including a substrate, a pair of a source electrode and a drain electrode, an organic semiconductor layer provided between the source electrode and the drain electrode, and a gate electrode provided in association with the organic semiconductor layer with a gate insulating layer interposed therebetween, wherein a step of forming the gate insulating layer includes forming an organic insulating layer containing an insulating organic material and forming a barrier layer having process resistance on the organic insulating layer.

### BRIEF DESCRIPTION OF DRAWINGS

FIG. 1 A schematic diagram showing a section view of an exemplary organic transistor according to an embodiment of the present invention.

FIG. 2 A schematic diagram showing a section view of an exemplary top-contact type organic transistor according to the embodiment of the present invention.

FIG. 3 A schematic diagram showing a section view of an exemplary top-gate type organic transistor according to an embodiment of the present invention.

FIG. 4 A flow chart showing a method of manufacturing an organic transistor in Example 1 of the present invention.

### BEST MODE FOR CARRYING OUT THE INVENTION

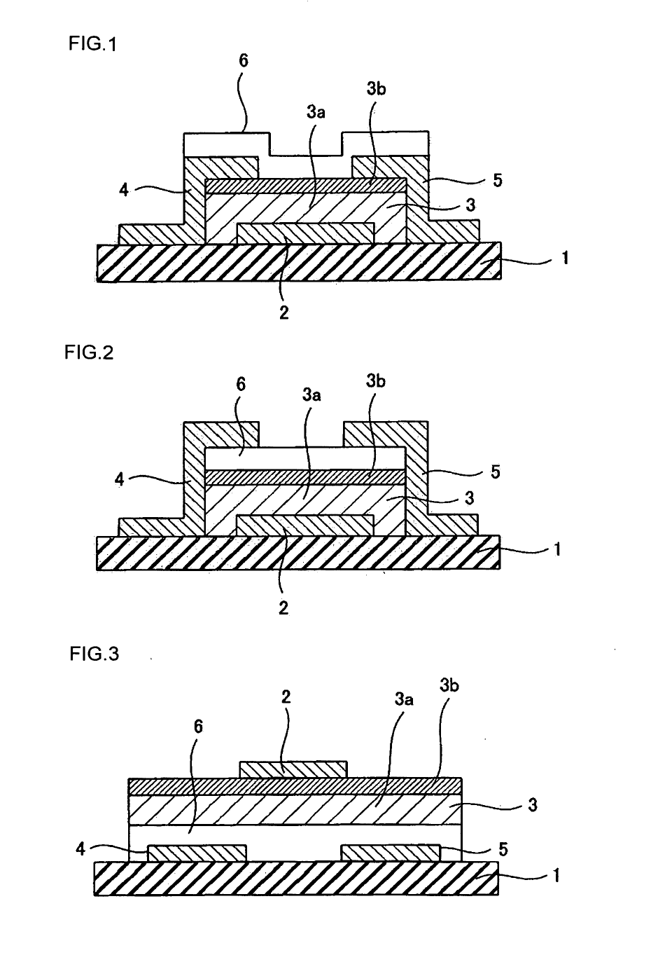

An embodiment according to the present invention will hereinafter be described with reference to FIGS. 1 to 4. The present invention is not limited by the illustration in the following description.

An organic transistor according to the present invention includes a substrate, a pair of a source electrode and a drain electrode, an organic semiconductor layer provided between the source electrode and the drain electrode, and a gate electrode provided in association with the organic semiconductor layer with a gate insulating layer interposed therebetween. When a voltage is applied to the organic semiconductor layer from the gate electrode via the gate insulating layer during application of a voltage between the source electrode and the drain electrode, an electric current passes through the organic semiconductor layer from the source electrode to the drain electrode.

The present invention is characterized in that the gate insulating layer includes an organic insulating layer containing an insulating organic material and a barrier layer covering the surface of the organic insulating layer and having process resistance. The structure allows prevention of damage to the organic insulating layer during process to avoid deteriorated insulation resistance of the gate insulating layer.

The gate insulating layer in the organic transistor desirably includes an organic insulating layer containing an organic material as a flexible material capable of being applied as a coating. If the organic insulating layer is brought into direct contact with the electrode or the organic semiconductor layer during process, the organic insulating layer may be penetrated or damaged by the ion component involved in the formation of the electrode, the ion component contained in the solvent associated with the formation of the organic semiconductor layer, and the organic semiconductor itself. In addition, the organic insulating layer may be altered by heat or light generated during process. To address this, the barrier layer formed on the surface of the organic insulating layer as in the present invention can protect the organic insulating layer to prevent damage to the organic insulating layer during process.

While the gate insulating layer including a polymeric material having a high dielectric constant is less resistant to solvent, the barrier layer having high resistance to solvent can be provided to prevent damage to the polymeric material from a solvent or the like during process. In addition, since the barrier layer can be formed by coating application as described later, the manufacturing steps can be simplified.

As shown in FIG. 1, an exemplary organic transistor is provided in which a gate electrode 2 is formed on a substrate 1, a gate insulating layer 3 is formed on the gate electrode 2, a source electrode 4 and a drain electrode 5 in a pair are formed to space on the gate insulating layer 3, and an organic semiconductor layer 6 is formed thereon in contact with the gate insulating layer 3 between the source electrode 4 and the drain electrode 5. The gate insulating layer 3 includes an organic insulating layer 3a on the gate electrode 2 and a barrier layer 3b on the organic insulating layer 3a. While the source electrode 4, the drain electrode 5, and the organic insulating layer 6 are formed by treatment with a solvent or the like over the gate insulating layer 3, the organic insulating layer 3a can be protected by the barrier layer 3b to prevent damage from a solvent or the like. The barrier layer 3b can protect the organic insulating layer 3a from heat and light during the treatment.

FIG. 2 shows an example of a top-contact type organic transistor. In FIG. 2, a gate electrode 2, an organic insulating layer 3a, a barrier layer 3b, and an organic semiconductor layer 6 are formed in order over a substrate 1, and a source electrode 4 and a drain electrode 5 are formed to space on the organic semiconductor layer 6. In such a structure, the barrier layer 3b can protect damage to the organic insulating layer 3a during the formation of the organic semiconductor layer 6.

FIG. 3 shows an example of a top-gate type organic transistor. In FIG. 3, a source electrode 4 and a drain electrode 5 are formed to space on a substrate 1, an organic semiconductor layer 6 is formed on the source electrode 4 and the drain electrode 5 and is interposed therebetween, and an organic insulating layer 3a, a barrier layer 3b, and a gate electrode 2 are formed in order over the organic semiconductor layer 6. In such a structure in which the gate electrode 2 is formed after the formation of the gate insulating layer 3, the barrier layer 3b can protect damage to the organic insulating layer 3a from a solvent or the like during the formation of the gate electrode 2.

The barrier layer of the gate insulating layer preferably has process resistance. Specifically, it preferably has resistance to alkaline and acid solvents used during process, and heat resistance and light resistance.

The barrier layer is preferably formed of an inorganic film provided through a coating application process or a vacuum process. Such an inorganic film has resistance to solvent used during process such as a chloroform, DMF (dimethylformamide), MFK (methyl ethyl ketone), and acetone, and can maintain planarity without any damage to the surface thereof even when these solvents are used over the inorganic film. If these solvents are brought into direct contact with the organic insulating layer, the surface of the organic insulating layer may be solved to reduce the surface roughness. However, the organic insulating layer is covered with the inorganic film to enable prevention of damage to the organic insulating layer during process.

The inorganic film can be formed by applying a coating of inorganic polymeric material onto the underlying organic insulating layer and changing the inorganic polymeric material into an appropriate inorganic material by heating, UV treatment, or a combination of UV treatment and ozone treatment. Examples of such an inorganic polymeric material include polymetalloxane containing an M-O—Si (where M represents a metal) bond or polysilazane containing a Si—N bond. An example of polymetalloxane is polysiloxane containing a Si—O—Si bond where M is Si or polytitano-metalloxane containing Ti. These materials can be subjected to heating to provide an inorganic film mainly containing silicon oxide and/or titanium oxide. The heating of the inorganic polymeric material is preferably performed at a temperature lower than a decomposition temperature of the underlying organic insulating layer, and specifically, at 200° C. or lower. According to the coating application process, the dielectric constant of the provided inorganic barrier layer ranges from 2.0 to 48 which is a typical dielectric constant of TiO₂. Alternatively, the inorganic polymeric material can be formed into the inorganic film by performing UV treatment or a combination of UV treatment and ozone treatment instead of the heating.

The coating application of the inorganic polymeric material is performed by spin coating or dip coating, for example. If necessary, the inorganic polymeric material is solved in a solvent such as 1-butanol and then applied.

The inorganic film thus formed has resistance to both alkaline and acid solvents and resistance to heat and light to allow prevention of damage to the organic insulating layer during process. Since the inorganic film can be formed by the coating application, the resulting film can be provided homogeneously with low cost. The inorganic film can be formed by the heating at 200° C. or lower, or the UV treatment or the combination of UV treatment and ozone treatment instead of the heating, thereby preventing thermal damage to the underlying organic insulating layer.

The inorganic film can be provided by a vacuum process such as a vacuum deposition method, a vacuum sputtering method, or a CVD method. Such a vacuum process can be used to form an inorganic film containing a metal oxide such as silicon oxide or a metal nitride such as silicon nitride. The vacuum process allows formation of the homogeneous inorganic film having a dense structure to prevent penetration of the solvent or the like into the organic insulating layer during process more effectively.

When the barrier layer is formed of the inorganic film, the surface of the inorganic film can be altered by a silane coupling agent to enhance affinity for the overlying organic semiconductor layer.

The battier layer has an average surface roughness of 0.1 nm to 50 nm, and preferably 1.5 nm or lower. A barrier layer having a roughness lower than the range is difficult to form homogeneously, while a barrier layer having a roughness higher than the range may affect the material of the layer in contact with the barrier layer to reduce the transistor performance.

The barrier layer has a thickness of 5 nm to 700 nm, and preferably 500 nm or lower. A barrier layer having a thickness lower than the range is difficult to provide homogeneously in view of a molecular thickness of approximately 5 nm, while a barrier layer having a thickness higher than the range makes up a considerable proportion to the organic insulating layer to prevent the advantageous use of the characteristics of the organic insulating layer in the light of the fact that the gate insulating layer is allowed to have a thickness of approximately 1 μm.

The organic insulating layer of the gate insulating layer is formed of an insulating organic material, preferably a flexible material capable of being applied as a coating. It preferably has resistance to solvent and heat involved in forming the barrier layer on the organic insulating layer. Since the barrier layer can be formed by the coating application at low temperature as described above and requires no solvent when the vacuum process is used, the barrier layer can be formed without any damage to the underlying organic insulating layer.

An example of the organic insulating layer is a cured mixture of PVP (polyvinyl phenol) and a melamine derivative. Such a polymeric material does not necessarily need to be cured as long as it has resistance to solvent and heat. Other examples thereof include polyimide, polysilsesquioxane, and bis-benzocyclobutene.

The organic insulating layer can be formed by the coating application. For example, a polymeric material such as a mixture of PVP and a melamine derivative is solved in a solvent, applied onto an underlying layer, dried as appropriate, and cured as appropriate.

The organic insulating layer preferably has a thickness of 50 nm to 1 μm. An extremely small thickness may cause a gate leak during operation, while an extremely large thickness may reduce the field effect to require a high voltage during operation.

The organic insulating layer thus formed has a dielectric constant of 2.0 to 18.

The substrate is not limited particularly and a glass substrate can be used, for example. As long as the barrier layer can be processed at a temperature of 200° C. or lower, it is possible to use a plastic substrate such as PES (polyether sulphone) or PC (polycarbonate), a bonded substrate including glass and plastic, or a substrate coated with an alkaline barrier film or a gas barrier film.

The organic semiconductor layer may be formed of an organic material exhibiting semiconductor characteristics. Pentacene can be used, and low-molecular-weight materials can be used such as a phthalocyanine-based derivative, a naphthalocyanine-based derivative, an azo compound-based derivative, a perylene-based derivative, an indigo-based derivative, a quinacridone-based derivative, a polycyclic quinone-based derivative such as anthraquinone, a cyanine-based derivative, a fullerene derivative, or a nitride-containing cyclic compound derivative such as indole, carbazole, oxazole, inoxazole, tiazole, imidazole, pyrazole, oxaadiazole, pyrazoline, or triazole, a hydrazine derivative, a triphenylamine derivative, a triphenylmethane derivative, a quinone compound derivative such as stilbene or anthraquinone diphenoquinone, a porphyrin derivative, and a polycyclic aromatic compound derivative such as anthracene, pyrene, phenanthrene, and coronene. Polymeric materials can be used such as an aromatic-based conjugate polymer such as polyparaphenylene, an aliphatic-based conjugate polymer such as polyacetylene, a heterocyclic conjugate polymer such as polypinol or polythiophene, a hetero atom-containing conjugate polymer such as polyalniline or polyphenylene sulfide, a carbon-based conjugate polymer including a composite conjugate polymer having alternately bonded unit structures of conjugate polymer such as poly (phenylene vinylene), poly (anilene vinylene), or poly (thionylene vinylene). It is also possible to use a polymer including polysilane or origosilane such as a disilanylene carbon-based conjugate polymer structure including a disilanylene arylene polymer, (disilanylene) ethenylene polymer, or (disilanylene) ethynylene polymer alternately linked with a carbon-based conjugate structure. Other examples include a polymer chain formed of an inorganic element such as phosphorus or nitrogen and a polymer including an aromatic-based ligand of polymer chain such as phthalocyanate polysiloxane, a polymer including thermally treated and fused perylene such as perylene tetracarboxylic acid, a ladder polymer provided by thermally treating a polyethylene derivative including a cyano group such as polyacrylonitrile, and a composite material including an intercalated organic compound in perovskite.

The materials of the source electrode, the drain electrode, and the gate electrode are not limited particularly as long as sufficient conductivity is provided. Examples thereof include metal such as Cr, Pt, Au, W, Ru, Ir, Al, Sc, Ti, V, Mn, Fe, Co, Ni, Zn, Ga, Y, Zr, Nb, Mo, Tc, Rh, Pd, Ag, Cd, Ln, Sn, Ta, Re, Os, Tl, Pb, La, Ce, Pr, Nd, Pm, Sm, Eu, Gd, Tb, Dy, Ho, Er, Tm, Yb, or Lu, or a stack thereof, or a compound thereof. It is also possible to use a metal oxide such as ITO (Indium Tin Oxide) or IZO (Indium Zinc Oxide) and an organic conductive material including a conjugate polymeric compound such as polyaniline, polythiophene, and polypyrrole.

As described above, according to the embodiment of the present invention, in the organic transistor including the substrate, the pair of the source electrode and the drain electrode, the organic semiconductor layer provided between the source electrode and the drain electrode, and the gate electrode provided in association with the organic semiconductor layer with the gate insulating layer interposed therebetween, the gate insulating layer includes the organic insulating layer containing the insulating organic material and the barrier layer covering the surface of the organic insulating layer and having the process resistance, so that the barrier layer can prevent damage to the organic insulating layer during process.

In the method of manufacturing the organic transistor including the substrate, the pair of the source electrode and the drain electrode, the organic semiconductor layer provided between the source electrode and the drain electrode, and the gate electrode provided in association with the organic semiconductor layer with the gate insulating layer interposed therebetween, the step of forming the gate insulating layer includes forming the organic insulating layer containing the insulating organic material and forming the barrier layer having the process resistance on the organic insulating layer, so that the barrier layer can prevent damage to the organic insulating layer during process.

### Examples

Examples of the present invention will hereinafter be described. The present invention is not limited by the examples.

### Test Example 1

In examples 1 and 2 and comparative examples 1 and 2 below, the gate leak current was measured after process and the degree of damage during process was evaluated from the measurement results.

### Example 1

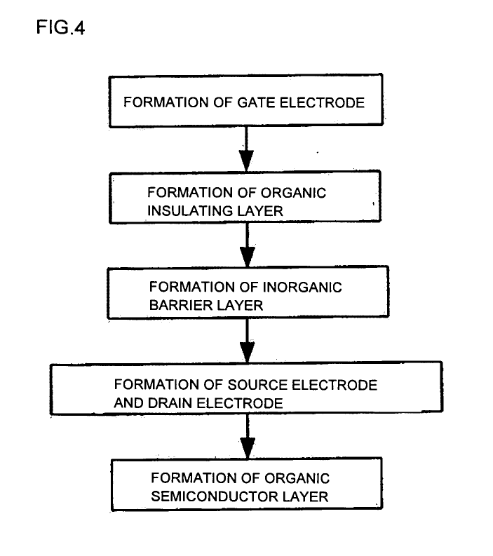

In Example 1, the organic transistor shown in FIG. 1 was formed. FIG. 4 shows a flow chart illustrating the method of manufacturing the organic transistor in Example 1.

Cr was deposited as the gate electrode 2 on the glass substrate 1 and was patterned by etching.

A solution provided by mixing 8 wt % polyvinyl phenol (Mw=20000) and 4 wt % polymelamine methylate formaldehyde copolymer (Mn=511) in PEGMEA (propylene glycol monomethylether acetate) was applied onto the gate electrode 2 by spin coating at 2000 rpm and cured by drying at 100° C. for two minutes and heating at 200° C. for five minutes to form the organic insulating layer 3a. The thickness of the organic insulating layer was 370 nm in SEM observation (this applies to the following).

Next, a solution of 10 wt % polytitano-metalloxane solved in 1-butanol was applied onto the organic insulating layer 3a by spin coating at 1000 rpm and was formed into an inorganic film by drying at 100° C. for two minutes and heating at 200° C. for five minutes to provide the barrier layer 3b. The thickness of the barrier layer was 100 nm.

Then, the source electrode 4 and the drain electrode 5 were formed on the barrier layer 3b by patterning Au through photolithography with vacuum deposition. Pentacene was deposited thereon by vacuum deposition to form the organic semiconductor layer 6 to provide the organic transistor.

### Example 2

In Example 2, the organic transistor was formed in the same manner as in Example 1 described above except for the organic semiconductor layer 6 formed by applying a 1 wt % solution of chloroform of poly-3-hexylthiophene onto the source electrode 4 and the drain electrode 5 by spin coating at 1000 rpm. The organic insulating layer and the barrier layer had thicknesses of 370 nm and 100 nm, respectively.

### Comparative Example 1

In comparative example 1, the gate insulating layer does not include the barrier layer but consists of the organic insulating layer in Example 1 described above. Since the remaining configuration is the same as that of Example 1, description thereof is omitted. The organic insulating layer had a thickness of 370 nm.

### Comparative Example 2

In comparative example 2, the gate insulating layer does not include the barrier layer but consists of the organic insulating layer in Example 2 described above. Since the remaining configuration is the same as that of Example 2, description thereof is omitted. The organic insulating layer had a thickness of 370 nm.

The gate leak current was measured after process in Examples and Comparative Examples described above. The results are shown in Table 1.

TABLE 1

| | Gate leak current (A) |
|---|---|
| Example 1 | 5 × 10⁻¹² |
| Example 2 | 7 × 10⁻¹² |
| Comparative Example 1 | 2 × 10⁻¹¹ |
| Comparative Example 2 | 3 × 10⁻⁹ |

As shown in Table 1, in each of the organic transistors including the barrier layers on the organic insulating layers in Examples 1 and 2, the gate leak current after process is reduced to show that the barrier layer can reduce damage to the organic insulating layer during process.

### Test Example 2

The surface roughness during process was measured in Example 3 and Comparative Example 3 below, and the degree of damage during process was evaluated from the results.

### Example 3

Cr was deposited as the gate electrode 2 on the glass substrate 1 and was patterned by etching.

A solution provided by mixing 8 wt % polyvinyl phenol (Mw=20000) and 4 wt % polymelamine methylate formaldehyde copolymer (Mn=511) in PEGMEA (propylene glycol monomethylether acetate) was applied onto the gate electrode 2 by spin coating at 2000 rpm and cured by drying at 100° C. for two minutes and heating at 200° C. for five minutes to form the organic insulating layer 3a. The thickness of the organic insulating layer was 370 nm.

Next, a solution of 10 wt % polytitano-metalloxane solved in 1-butanol was applied onto the organic insulating layer 3a by spin coating at 1000 rpm and was formed into an inorganic film by drying at 100° C. for two minutes and heating at 200° C. for five minutes to provide the barrier layer 3b. The thickness of the barrier layer was 100 nm.

Then, the source electrode 4 and the drain electrode 5 were formed on the barrier layer 3 by patterning Au through photolithography with vacuum deposition. Acetone was used during lift-off.

### Comparative Example 3

In comparative example 3, the gate insulating layer does not include the barrier layer but consists of the organic insulating layer in Example 3 described above. Since the remaining configuration is the same as that of Example 3, description thereof is omitted. The organic insulating layer had a thickness of 370 nm.

The surface roughness was measured before and after the formation of the source electrode and the drain electrode by an atomic force microscope (AFM) in Example 3 and Comparative Example 3 described above. The results are shown in Table 2.

TABLE 2

| | | Comparative |
|---|---|---|
| | Example 3 | Example 3 |
| Before formation of source and | 0.20 nm | 0.20 nm |
| drain electrodes | | |
| After formation of source and | 0.20 nm | 0.27 nm |
| drain electrodes | | |

As shown in Table 2, in Example 3 in which the organic insulating layer is protected by the barrier layer, the surface roughness is at the same level before and after the formation of the electrodes to show that damage can be prevented during the formation of the electrodes. On the other hand, in Comparative Example 3 in which the gate insulating layer consists of the organic insulating layer, the surface roughness has a larger value after the formation of the electrodes to show that the organic insulating layer was damaged by the formation of the electrodes.

While the present invention has been described with reference to the specific embodiments, it is apparent to those skilled in the art that various modifications can be made without departing from the scope of the present invention. Thus, the technical scope of the present invention is not limited to the embodiment described above but should be defined on the basis of the claims and the equivalent thereof.

1. An organic transistor comprising:
a substrate;
a pair of a source electrode and a drain electrode;
an organic semiconductor layer provided between the source electrode and the drain electrode; and
a gate electrode provided in association with the organic semiconductor layer with a gate insulating layer interposed therebetween,
wherein the gate insulating layer includes an organic insulating layer containing an insulating organic material and a barrier layer covering a surface of the organic insulating layer and having process resistance, and
the barrier layer is an inorganic film containing an inorganic material provided by changing an inorganic polymer through heating at a temperature equal to or lower than 200° C., the inorganic polymer being polymetalloxane applied onto the organic insulating layer.

2. The organic transistor according to claim 1, wherein the gate electrode, the organic insulating layer, the barrier layer, and the organic semiconductor layer are placed in order over the substrate.

3. The organic transistor according to claim 1, wherein the organic semiconductor layer, the organic insulating layer, the barrier layer, and the gate electrode are placed in order over the substrate.

4-6. (canceled)

7. The organic transistor according to claim 1, wherein the barrier layer has an average roughness from 0.1 to 50 nm.

8. The organic transistor according to claim 1, wherein the barrier layer has a thickness from 5 to 700 nm.

9. A method of manufacturing an organic transistor comprising:
a substrate;
a pair of a source electrode and a drain electrode;
an organic semiconductor layer provided between the source electrode and the drain electrode; and
a gate electrode provided in association with the organic semiconductor layer with a gate insulating layer interposed therebetween,
wherein a step of forming the gate insulating layer includes forming an organic insulating layer containing an insulating organic material and forming a barrier layer having process resistance on the organic insulating layer, and
the barrier layer is formed by changing an inorganic polymer into an inorganic material through heating at a temperature equal to or lower than 200° C., the inorganic polymer being polymetalloxane applied onto the organic insulating layer.

10. The method of manufacturing an organic transistor according to claim 9, wherein the gate electrode, the organic insulating layer, the barrier layer, and the organic semiconductor layer are formed in order over the substrate.

11. The method of manufacturing an organic transistor according to claim 9, wherein the organic semiconductor layer, the organic insulating layer, the barrier layer, and the gate electrode are formed in order over the substrate.

12-13. (canceled)

14. The method of manufacturing an organic transistor according to claim 9, wherein the heating is performed at a temperature lower than a decomposition temperature of the organic insulating layer.

15. (canceled)

16. The method of manufacturing an organic transistor according to claim 9, wherein the barrier layer is formed to have an average roughness from 0.1 to 50 nm.

17. The method of manufacturing an organic transistor according to claim 9, wherein the barrier layer is formed to have a thickness from 5 to 700 nm.
